(19) United States
(12) Patent Application Publication
(10) Pub. No.: US 2010/0330809 A1
(43) Pub. Date: Dec. 30, 2010

(54) POLISHING LIQUID FOR METALS

(75) Inventors: Tadashi INABA, Haibara-gun (JP); Takahiro MATSUNO, Haibara-gun (JP); Makoto KIKUCHI, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/877,010

(22) Filed: Sep. 7, 2010

Related U.S. Application Data
(63) Continuation of application No. 11/648,618, filed on Jan. 3, 2007.

(30) Foreign Application Priority Data
Feb. 24, 2006 (JP) 2006-48470
Mar. 27, 2006 (JP) 2006-85667

(51) Int. Cl. H01L 21/306

(52) U.S. Cl. 438/693; 257/E21.23

(57) ABSTRACT

A liquid for polishing metals, which is used in the chemical and/or mechanical flattening of a semiconductor device, the polishing liquid being characterized in that it comprises at least one member selected from the group consisting of tetrazoles or triazoles represented by any one of the following general formulas (I) to (III):

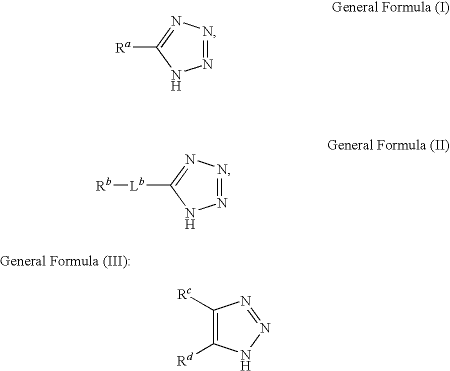

wherein, R^{a} represents at least one substituent selected from the group consisting of a sulfo, an amino, a phosphono, a carbamoyl, a carbamide, a sulfamoyl, and a sulfonamide group; R^{b} represents at least one substituent selected from the group consisting of a hydroxyl, a carboxyl, a sulfo, an amino, a phosphono, a carbamoyl, a carbamide, a sulfamoyl, and a sulfonamide group; and L^{b} represents a divalent connecting group; and R^{c} and R^{d} each independently represent a hydrogen atom or a substituent, and at least one of R^{c} and R^{d} represent a hydroxyl, a carboxyl, a sulfo, an amino, a phosphono, a carbamoyl, a carbamide, a sulfamoyl, and a sulfonamide group or a group: -L^{a}-R^{e}; wherein L^{a} represents a divalent connecting group; R^{e} represents a hydroxyl, a carboxyl, a sulfo, an amino, a phosphono, a carbamoyl, a carbamide, a sulfamoyl or a sulfonamide group; R and R′ each independently represent a group selected from the group consisting of a hydrogen atom, alkyl groups and aryl groups; and R″ independently represents a group selected from the group consisting of alkyl groups and aryl groups.

### CROSS-REFERENCE TO RELATED APPLICATION

This application is a Rule 53(b) Continuation of U.S. application Ser. No. 11/648,618 filed Jan. 3, 2007, which claims foreign priority based on Japanese Patent Application No. 2006-48470 filed Feb. 24, 2006 and Japanese Patent Application No. 2006-85667 filed Mar. 27, 2006. The above-noted applications are incorporated herein by reference in their entirety.

### BACKGROUND OF THE INVENTION

The present invention relates to the production of a semiconductor device and, in particular, to a method for the preparation of an organic material for abrasing or polishing metals in the wiring step of a semiconductor device as well as a polishing liquid for metals (also referred to as “metal-polishing liquid”).

In the development of semiconductor devices typical of semiconductor large scale integrated circuits (hereunder referred to as “LSI”), there have been desired for the achievement of high density packaging and an increased integration density of semiconductor devices through the fine patterning of wirings and the realization of laminated or stacked structures of the semiconductor device for the purpose of further improvement of the packaging density and the operation speed of the devices. As techniques for achieving the foregoing purposes, there have conventionally been used a variety of methods such as chemical and/or mechanical polishing technique(s) (hereunder referred to as “CMP” technique(s)), which comprise the step of polishing a metal thin film used in, for instance, insulating thin films (such as SiO2 thin films) or wirings, to thus make the surface of a substrate smooth and/or to remove any excess metal thin film during the formation of wirings.

The CMP technique in general comprises the steps of applying a polishing pad onto a circular polishing board (platen); impregnating the surface of the polishing pad with a polishing liquid; pressing the surface of the substrate (wafer) against the pad; and rotating both of the polishing board and the substrate while applying a desired pressure (polishing pressure) to the substrate from the back surface thereof, to thus make the surface of the substrate smooth by the action of the mechanical frictional force thus generated.

The liquid for polishing a metal used in the CMP technique is in general a solution comprising abrasive grains (such as alumina, silica particles) and an oxidizing agent (such as hydrogen peroxide, persulfuric acid) and it has been believed that the oxidizing agent present in the liquid serves to oxidize the surface of a metal substance, while the abrasive grains serves to remove the resulting metal oxide film formed thereon to thus polish the metal substance.

If the CMP technique is carried out using such a metal-polishing liquid containing solid abrasive grains, however, various problems often arise, for instance, the formation of defects through polishing (scratch marks); a phenomenon (called thinning) in which the whole surface of a metal substrate to be processed is excessively polished; a phenomenon (called dishing) in which the metal surface to be polished is not even, but only the central portion thereof is excessively removed through polishing to thus form a dish-like recess; and a phenomenon (called erosion) in which the dielectric substance arranged between metal wirings is excessively removed through polishing, while the surface of a plurality of metal wirings form dish-like concave areas thereon.

To solve such problems of the conventional solid abrasive grain-containing polishing liquid, there has been proposed, for instance, a liquid for polishing a metal substance, which comprise hydrogen peroxide, malic acid, benzotriazole, ammonium polyacrylate and water (see, for instance, Japanese Un-Examined Patent Publication 2001-127019). According to the method using this polishing liquid, only the metal film present on the convex portion of a semiconductor substrate is selectively removed through the CMP treatment, while the metal film remains on the concave portion of the semiconductor substrate to thus give a desired pattern of the conductive material. However, this method suffers from such a problem that it cannot achieve any satisfactory polishing speed. This is because, the CMP processing step would go forward even when using a polishing pad significantly and mechanically softer than that used in the polishing operation which makes use of a conventional solid abrasive grain-containing polishing liquid.

On the other hand, there has recently been developed an LSI device provided with wirings made of copper, as a metal for forming the same, which has a considerably low electric resistance, in place of tungsten and/or aluminum which have widely been used conventionally, while aiming at the development of semiconductor devices of more improved quality. As the further reduction of the size of the wirings, aiming at the achievement of a high packaging density, there has been desired for the development of such wirings of copper, which can satisfy the requirements for the improved conductivity and for the improved resistance to electron-migration. As a result, there has been proposed a technique, which makes use of, as a conductive material for forming wirings, a copper alloy comprising copper having a high purity and a trace amount of a third component such as silver. At the same time, there has been desired for the development of a fast metal-polishing means which can ensure a high productivity without accompanying any contamination of these highly fine and highly pure materials.

Recently, the diameter of a wafer used in the preparation of LSI devices has been increased for the improvement of the productivity and there have recently been used widely wafers each having a diameter of not less than 200 mm and even those having a diameter of not less than 300 mm. In this connection, the difference in the polishing speed between the central and peripheral portions of a wafer becomes larger and larger as the size of the wafer used gradually increases and accordingly, there has strongly been desired for the improvement of the uniformity or evenness within the whole surface of such a large scale wafer.

As a chemical polishing method that is free of any means for mechanically polishing copper or a copper alloy, there have been known chemical polishing techniques, which make use of only the dissolving power (see, for instance, Japanese Un-Examined Patent Publication Sho 49-122432). However, this method suffers from problems such that it may cause phenomena such as the dishing, which in turn leads to the occurrence of other problems and the method may ensure the evenness of the surface of a wafer with great difficulty, as compared with the CMP technique in which the metal film present on the convex portions of such a large sized wafer is selectively removed through the chemical/mechanical polishing.

In addition, there have also been proposed an aqueous dispersion for use in chemical and/or mechanical polishing, which can control any deterioration of a polishing pad, for the purpose of flattening any stepped portion present on the surface of a subject to be polished (see, for instance, Japanese Un-Examined Patent Publication 2001-279231); a processing liquid containing a chelating agent selected from imino-diacetic acid and salts thereof, useful for correcting or modifying the wafer surface (see, for instance, Japanese Un-Examined Patent Publication Tokuhyo 2002-538284); and a chemical/mechanical polishing composition comprising an α-amino acid (see, for instance, Japanese Un-Examined Patent Publication 2003-507894).

These techniques would permit the improvement in the ability of polishing copper wirings. However, there has still been desired for the development of a polishing liquid having excellent copper/tantalum selectivity upon the flattening of the region in the proximity to the wirings since tantalum and alloys thereof, which have frequently been used as barrier metals for copper wirings, are harder as compared with copper.

### DISCLOSURE OF THE INVENTION

As has been discussed above in detail, there has been desired for the development of a CMP slurry which can allow the quick polishing of wirings formed from metal copper and alloys thereof in order to improve the productivity of the LSI devices and the present invention has thus been developed for satisfying such technical requirement.

Accordingly, it is an object of the present invention to provide a polishing liquid for metals, which can ensure a high polishing speed, has an improved selectivity to copper/tantalum in polishing operations and which in turn permits the production of an LSI device having an improved flatness and free of any dishing phenomenon.

The inventors of this invention have variously investigated the problems associated with the foregoing conventional liquids for polishing metals, have found that these problems can efficiently be solved by the use of a liquid for polishing metals detailed below and have thus completed the present invention. More specifically, the present invention relates to the following inventions:

(1) A liquid for polishing metals, which is used in the chemical and/or mechanical flattening of a semiconductor device, the polishing liquid being characterized in that it comprises at least one member selected from the group consisting of tetrazoles or triazoles represented by any one of the following general formulas (I) to (III).

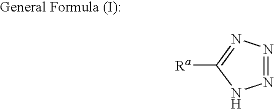

wherein, R^{a} represents at least one substituent selected from the group consisting of a sulfo group, an amino group, a phosphono group (—PO₃H₂), a carbamoyl group (—CONRR′), a carbamide group (—NHCOR″), a sulfamoyl group (—SO₂NH₂), and a sulfonamide group (—NHSO₂R″); R and R′ each independently represent a group selected from the group consisting of a hydrogen atom, alkyl groups and aryl groups; and R″ independently represents a group selected from the group consisting of alkyl groups and aryl groups.

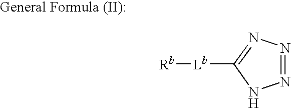

wherein, R^{b} represents at least one substituent selected from the group consisting of a hydroxyl group, a carboxyl group, a sulfo group, an amino group, a phosphono group (—PO₃H₂), a carbamoyl group (—CONRR′), a carbamide group (—NHCOR″), a sulfamoyl group (—SO₂NH₂), and a sulfonamide group (—NHSO₂R″); R and R′ each independently represent a group selected from the group consisting of a hydrogen atom, alkyl groups and aryl groups; R″ independently represents a group selected from the group consisting of alkyl groups and aryl groups; and L^{b} represents a divalent connecting group.

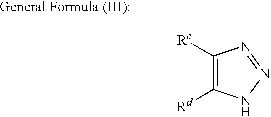

wherein, R^{c} and R^{d} each independently represent a hydrogen atom or a substituent, and at least one of R^{c} and R^{d} represent a hydroxyl group, a carboxyl group, a sulfo group, an amino group, a phosphono group (—PO₃H₂), a carbamoyl group (—CONRR′), a carbamide group (—NHCOR″), a sulfamoyl group (—SO₂NH₂), a sulfonamide group (—NHSO₂R″) or a group: -L^{a}-R^{e}; L^{a} represents a divalent connecting group; R^{e} represents a hydroxyl group, a carboxyl group, a sulfo group, an amino group, a phosphono group (—PO₃H₂), a carbamoyl group (—CONRR′), a carbamide group (—NHCOR″), a sulfamoyl group (—SO₂NH₂) or a sulfonamide group (—NHSO₂R″); R and R′ each independently represent a group selected from the group consisting of a hydrogen atom, alkyl groups and aryl groups; and R″ independently represents a group selected from the group consisting of alkyl groups and aryl groups.
(2) The liquid for polishing metals as set forth in the foregoing item (1), wherein it is principally used for polishing wirings made of copper, in the chemical/mechanical flattening of semiconductor devices.

In the chemical/mechanical polishing step for the production of a semiconductor device, the use of the liquid for polishing metals or the metal-polishing liquid of the present invention as a polishing liquid would permit the improvement of the speed of the chemical/mechanical polishing step and the achievement of an improved selectivity of the polishing step to copper/tantalum. Thus, the metal-polishing liquid would permit the production of an LSI device which is free of any dishing phenomenon and which has a highly improved surface flatness. Moreover, this would in turn permit the control, to a substantially low level, of the probability of generating any defect on the processed surface of a substrate due to local unevenness in the polishing-degree, for instance, phenomena of corrosion, scratch mark-formation, thinning and erosion.

### BEST MODE FOR CARRYING OUT THE INVENTION

The metal-polishing liquid of the present invention is characterized in that it comprises a specific tetrazole or triazole derivative specified below. More specifically, the metal-polishing liquid comprises a tetrazole derivative carrying at least one specific substituent on a carbon atom constituting the tetrazole ring (hereunder also referred to as “specific tetrazole derivative”, according to circumstances) or a 1,2,3-triazole derivative carrying at least one specific substituent on a carbon atom constituting the 1,2,3-triazole ring (hereunder also referred to as “specific 1,2,3-triazole derivative”, according to circumstances).

The tetrazole derivative represented by the general formula (I) used in the present invention never has any substituent on any nitrogen atom constituting the tetrazole ring and it has at least one substituent selected from the group consisting of a sulfo group (—SO₃H), an amino group, a phosphono group (—PO₃H₂), a carbamoyl group (—CONRR′), a carbamide group (—NHCOR″), a sulfamoyl group (—SO₂NH₂), and a sulfonamide group (—NHSO₂R″) on the 5-position (on the carbon atom) (R^{a}) of the tetrazole ring. Moreover, R and R′ each independently represent a group selected from the group consisting of a hydrogen atom, alkyl groups and aryl groups, and more preferably a hydrogen atom or an alkyl group having about 1 to 3 carbon atoms. In addition, R″ independently represents a group selected from the group consisting of alkyl groups and aryl groups and more preferably an alkyl group, in particular, an alkyl group having about 1 to 3 carbon atoms.

Moreover, the tetrazole derivative represented by the general formula (II) used in the present invention is one which is characterized in that it never has any substituent on any nitrogen atom constituting the tetrazole ring and it has at least one substituent selected from the group consisting of a hydroxyl group, a carboxyl group, a sulfo group, an amino group, a phosphono group (—PO₃H₂), a carbamoyl group (—CONRR′), a carbamide group (—NHCOR″), a sulfamoyl group (—SO₂NH₂), and a sulfonamide group (—NHSO₂R″), on the 5-position of the tetrazole ring through a divalent connecting group represented by L^{b}. Moreover, R and R′ each independently represent a group selected from the group consisting of a hydrogen atom, alkyl groups and aryl groups, and more preferably a hydrogen atom or an alkyl group having about 1 to 3 carbon atoms. In addition, R″ independently represents a group selected from the group consisting of alkyl groups and aryl groups and more preferably an alkyl group, in particular, an alkyl group having about 1 to 3 carbon atoms.

The divalent connecting group represented by L^{b} may be, for instance, an alkylene group, —S—, —O—, —NH—, —CO— or any combination thereof. Preferred divalent connecting groups include alkylene groups and more preferably alkylene groups having about 1 to 3 carbon atoms.

The connecting group L^{b} may likewise have a substituent other than R^{b}. Examples of such another substituent include alkyl groups having 1 to 3 carbon atoms and aryl groups having 6 to 12 carbon atoms, which may further have substituents. Examples of the latter are hydroxyl and carboxyl groups.

The tetrazole derivatives used in the present invention are preferably those represented by the foregoing general formula (II), more preferably those represented by the foregoing general formula (II) in which the substituent R^{b} represents a hydroxyl group or a carboxyl group and further preferably those represented by the foregoing general formula (II) in which the substituent R^{b} represents a carboxyl group. For instance, the tetrazole derivative may be 1H-tetrazole-5-acetic acid and 1H-tetrazole-5-succinic acid.

Specific examples of the tetrazole derivatives represented by the foregoing general formula (I) or (II) which can suitably be used in the present invention will be listed below, but the present invention is not restricted to these specific examples at all.

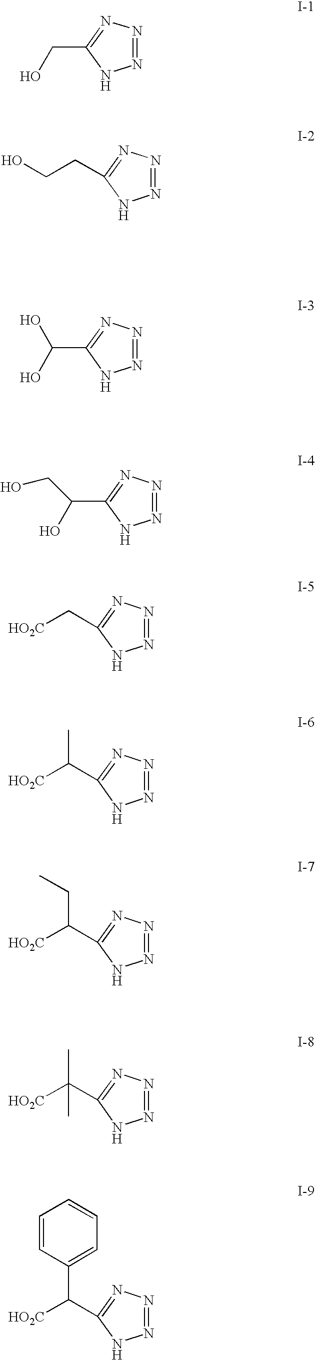

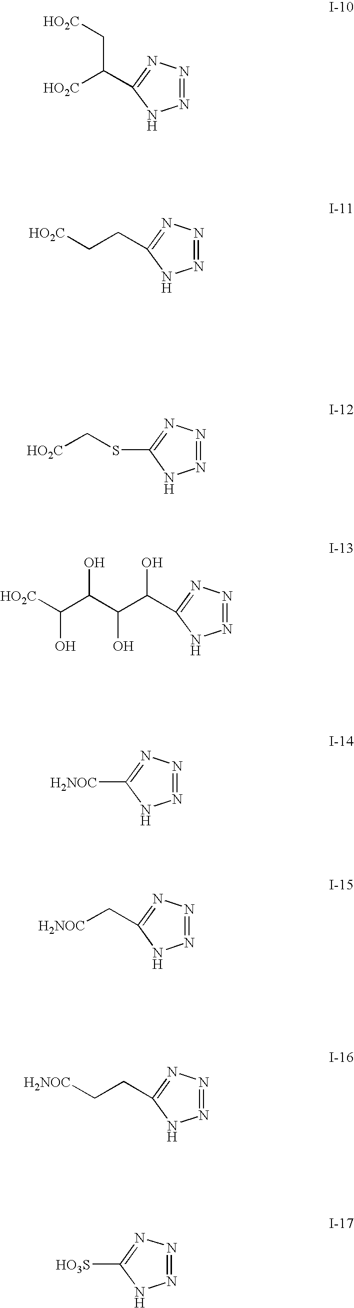

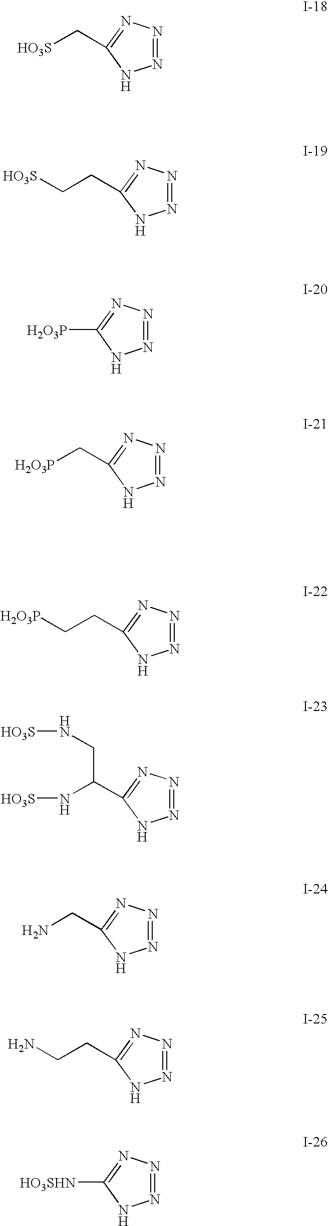

The tetrazole derivatives used in the present invention may be available on the market, or can be synthesized while taking into consideration the contents of the following articles: Chemische Berichte, 1901, 34:3120; Chemische Berichte, 1956, 89:2648; Journal of Medical Chemistry, 1986, 29:538-549; Carbohydrate Research, 1979, 73:323-326.

The 1,2,3-triazole derivative represented by the general formula (III) used in the present invention is one which is free of any substituent on the nitrogen atoms constituting the 1,2,3-triazole ring and which has a substituent selected from the group consisting of a sulfo group, an amino group, a carbamoyl group, a carbamide group, a sulfamoyl group, a sulfonamide group and -L^{a}-R^{e}, on at least 4- or 5-position of the 1,2,3-triazole ring (carbon atom).

In the general formula R^{c} and R^{d} each independently represent a hydrogen atom or a substituent, and at least one of R^{c} and R^{d} represent a hydroxyl group, a carboxyl group, a sulfo group, an amino group, a phosphono group (—PO₃H₂), a carbamoyl group (—CONRR′), a carbamide group (—NHCOR″), a sulfamoyl group (—SO₂NH₂), a sulfonamide group (—NHSO₂R″) or a group: -L^{a}-R^{e}. R and R′ each independently represent a member selected from the group consisting of a hydrogen atom, alkyl groups and aryl groups and more preferably a hydrogen atom or an alkyl group having 1 to 5 carbon atoms. R″ independently represents a group selected from the group consisting of alkyl groups and aryl groups and more preferably an alkyl group having 1 to 5 carbon atoms.

The foregoing substituent represented by at least one of R^{c} and R^{d} is preferably a group: -L^{a}-R^{e}.

Examples of the divalent connecting groups represented by L^{a} include an alkylene group, —S—, —O—, —NH—, —CO— and any combination thereof. The connecting groups are preferably alkylene groups, more preferably methylene and ethylene groups and most preferably a methylene group.

Examples of substituents represented by R^{e} include a hydroxyl group, a carboxyl group, a sulfo group, an amino group, a carbamoyl group (—CONRR′), a carbamide group (—NHCOR″), a sulfamoyl group (—SO₂NH₂) and a sulfonamide group (—NHSO₂R″). R and R′ each independently represent a member selected from the group consisting of a hydrogen atom, alkyl groups and aryl groups and more preferably a hydrogen atom or an alkyl group having 1 to 5 carbon atoms. R″ independently represents a member selected from the group consisting of alkyl groups and aryl groups and more preferably an alkyl group having 1 to 5 carbon atoms. The substituent represented by R^{c} is preferably a hydroxyl group or a carboxyl group and more preferably a carboxyl group.

When L^{a} represents an alkylene group having 2 to 6 carbon atoms, the alkylene group may further include a substituent thereon other than R^{e}. Examples of such substituents include alkyl groups each having about 1 to 5 carbon atoms and aryl groups each having about 6 to 12 carbon atoms and these substituents may likewise have substituents. Examples of the latter preferably used herein include hydroxyl and carboxyl groups.

Examples of other substituents represented by R^{c} or R^{d} include halogen atoms (such as fluorine, chlorine, bromine and iodine atoms), alkyl groups each having about 1 to 5 carbon atoms (such as linear, branched or cyclic alkyl groups, which may be a polycyclic alkyl group such as a bicycloalkyl group or which may include an active methine group), halogen atom-substituted alkyl groups (such as trifluoromethyl group), alkenyl groups each having about 2 to 6 carbon atoms, alkynyl groups each having about 2 to 6 carbon atoms, aryl groups each having about 6 to 12 carbon atoms, heterocyclic groups (irrespective of the position to be substituted), acyl groups, alkoxycarbonyl groups, aryloxycarbonyl groups, heterocyclo-oxycarbonyl groups, N-hydroxycarbamoyl groups, N-acylcarbamoyl groups, N-sulfonylcarbamoyl groups, N-carbamoyl-carbamoyl groups, thio-carbamoyl groups, N-sulfamoyl-carbamoyl groups, carbazoyl groups, oxalyl groups, oxamoyl groups, cyano groups, carbonimidoyl groups, formyl groups, alkoxy groups (including groups having repeated units such as ethyleneoxy and/or propyleneoxy groups), aryloxy groups, heterocyclic oxy groups, acyloxy groups, (alkoxy or aryloxy) carbonyloxy groups, carbamoyloxy groups, sulfonyloxy groups, (alkyl, aryl, or heterocyclic) amino groups, acylamino groups, ureido groups, thioureido groups, N-hydroxy-ureido groups, imido groups, (alkoxy or aryloxy) carbonylamino groups, sulfamoylamino groups, semicarbazide groups, thio-semicarbazide groups, hydrazino groups, ammonio groups, oxamoyl-amino groups, N-(alkyl or aryl) sulfonyl-ureido, groups, N-acyl-ureido groups, N-acyl-sulfamoylamino groups, hydroxy-amino groups, nitro groups, quaternary nitrogen atom-containing heterocyclic groups (such as pyridinio, imidazolio, quinolinio, isoquinolinio groups), isocyano groups, imino groups, mercapto groups, (alkyl, aryl, or heterocyclic) thio groups, (alkyl, aryl, or heterocyclic) dithio groups, (alkyl or aryl) sulfonyl groups, (alkyl or aryl) sulfinyl groups, or salts thereof, N-acyl-sulfamoyl groups, N-sulfonyl-sulfamoyl groups or salts thereof, phosphino groups, phosphinyl groups, phosphinyl-oxy groups, phosphinyl-amino groups, and silyl groups.

In this respect, the term “active methine group” herein used means a methine group which is substituted with two electron attractive groups and specific examples of the electron attractive groups include acyl, alkoxycarbonyl, aryloxycarbonyl, carbamoyl, alkylsulfonyl, arylsulfonyl, sulfamoyl, trifluoromethyl, cyano, nitro, carbonimidoyl groups.

Examples of the foregoing other substituents for R^{c} and R^{d} preferably include hydrogen atom and alkyl groups (having 1 to 5 carbon atoms). The foregoing other substituents for R^{c} and R^{d} most preferably include hydrogen atoms.

As the 1,2,3-triazole derivatives used in the present invention, preferably used herein include, for instance, those represented by the following general formula (IV) or (V) and more preferably used herein include, for instance, those represented by the general formula (IV). This is because the use thereof would permit the further control of the occurrence of the foregoing dishing phenomenon.

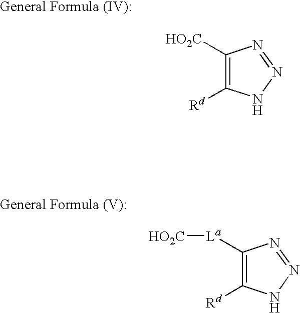

wherein, R^{d} has the same meaning specified above in connection with Formula (III) and preferred examples thereof are the same as those listed above in connection with Formula (III).

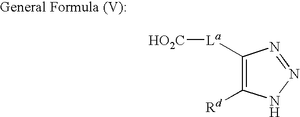

wherein, R^{d} and L^{a} have the same meanings as those specified above in connection with Formula (III) and preferred examples thereof are the same as those listed above in connection with Formula (III).

Specific examples of the 1,2,3-triazole derivatives, which can suitably be used in the present invention will be listed below, but the present invention is not restricted to these specific examples at all:

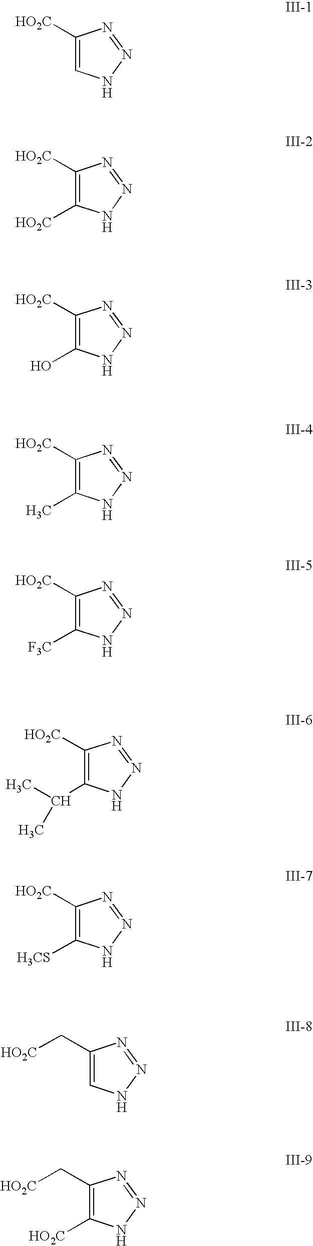

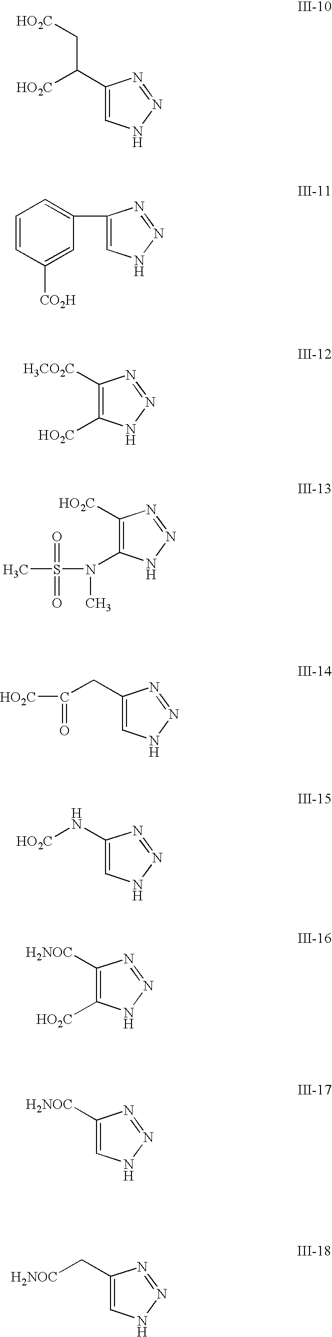

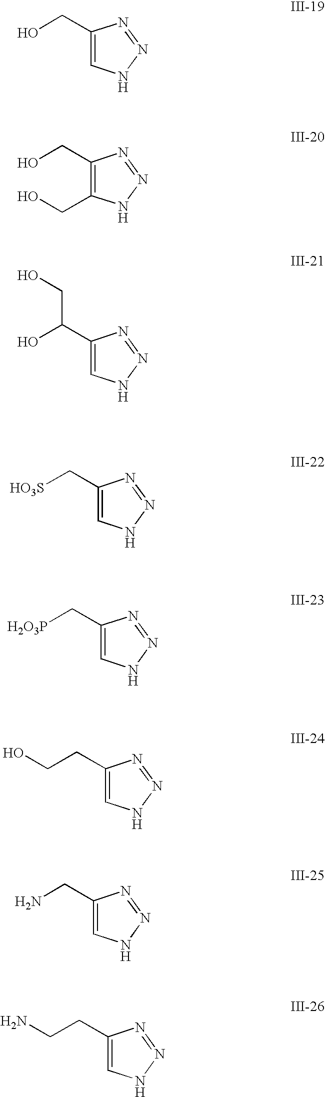

The 1,2,3-triazole derivatives used in the present invention can be synthesized while taking into consideration the contents of the following articles: Carbohydrate Research, 1974, 38:107-115; and Journal of Organic Chemistry, 1956, 21:190.

The metal-polishing liquid of the present invention may comprise one member selected from the group consisting of the foregoing specific tetrazole derivatives and specific 1,2,3-triazole derivatives, or any combination of at least two members selected from the group.

The total amount of the specific tetrazole derivative or the specific 1,2,3-triazole derivative to be incorporated into the metal-polishing liquid of the present invention preferably ranges from 0.00001 to 1 mole, more preferably 0.0001 to 0.5 mole and further preferably 0.0001 to 0.1 mole per one liter (1 L) of the metal-polishing liquid practically used in polishing (more specifically, when diluted with water or an aqueous solution, this corresponds to the polishing liquid obtained after the dilution; those appearing in the following description are likewise shown in the same way).

The metal-polishing liquid of the present invention is not specifically restricted in its formulation inasmuch as it comprises, as essential ingredients, at least one member selected from group consisting of the foregoing specific tetrazole derivatives and specific 1,2,3-triazole derivatives and at least one solvent or dispersion medium, but it is in general preferred that an oxidizing agent is added to the liquid prior to its practical use. Moreover, the metal-polishing liquid may likewise include the compounds used in the conventionally known metal-polishing liquids and selected depending on specific purposes, insofar as the addition thereof never adversely affects the intended effects of the present invention. Examples of such additives preferably used herein are organic acids (such as amino acid derivatives and/or carboxylic acid derivatives).

In general, the metal-polishing liquid comprises an oxidizing agent, a passive film-forming agent, an organic acid and abrasive grains, but the metal-polishing liquid of the present invention must not always comprise abrasive grains. The metal-polishing liquid of the present invention may further comprise other components and preferably used herein include, for instance, a surfactant, a water-soluble polymer, and various kinds of other additives. The metal-polishing liquid may comprise at least two of each component.

The “metal-polishing liquid” according to the present invention includes not only the polishing liquid (more specifically, the polishing liquid diluted at the user's own discretion) practically used in metal-polishing operations, but also any concentrated metal-polishing liquid as the stock solution. The term “liquid concentrate or concentrated polishing liquid” means a polishing liquid whose concentrations of every components or the solutes are high as compared with those of the polishing liquid practically used in metal-polishing operations and it is diluted with water or an aqueous solution prior to its practical use in metal-polishing operations. The factor of the dilution in general ranges from 1 to 20 times the volume of the stock solution or liquid concentrate. In the instant specification, the terms “concentration” and “liquid concentrate” are used on the basis of the idiomatic expressions thereof, which mean “concentrate” and “highly concentrated liquid” as compared with the polishing liquid put into practical use and therefore, these terms are used according to the way of using them different from those commonly used, which require a physical concentration operation such as the distillation.

In this connection, the amount of the components to be incorporated into the polishing liquid upon the preparation of a liquid concentrate thereof and whose solubility in water as determined at room temperature is less than 5% by mass, among the whole components of the polishing liquid, should preferably be controlled to a level of not more than 2 times and more preferably not more than 1.5 times the solubility thereof in water as determined at room temperature, in order to prevent the occurrence of any precipitation when cooling the liquid concentrate to 5° C.

The ingredients other than the foregoing specific tetrazole derivatives and specific 1,2,3-triazole derivatives, which can be used in the metal-polishing liquid of the present invention will now be described in more detail below.

### [Oxidizing Agent]

A compound (oxidizing agent) capable of oxidizing a metal to be polished is in general incorporated into the metal-polishing liquid of the present invention. In this respect, however, the oxidizing agent may be added thereto immediately before the practical use of the polishing liquid to prevent, for instance, any premature decomposition of the oxidizing agent. Accordingly, the term “metal-polishing liquid” used in this specification also includes a preliminary liquid which is free of any oxidizing agent and to which an oxidizing agent is added immediately before the practical use thereof. Examples of such oxidizing agents are hydrogen peroxide, peroxides, nitric acid salts, iodates, periodates, hypochlorites, chlorites, chlorates, perchlorates, persulfates, bichromates, permanganates, aqueous ozone (ozone-containing water), silver(II) salts and iron(III) salts.

Examples of iron(III) salts preferably used herein include inorganic iron(III) salts such as iron(III) nitrate, iron(III) chloride, iron(III) sulfate and iron(III) bromide; and organic complex salts of iron(III).

In case of using organic complex salts of iron(III), examples of complex salt-forming compounds usable herein for forming complex salts of iron(III) include acetic acid, citric acid, oxalic acid, salicylic acid, diethyl dithio-carbamic acid, succinic acid, tartaric acid, glycolic acid, glycine, alanine, aspartic acid, thio-glycolic acid, ethylene-diamine, triethylene-diamine, diethylene glycol, triethylene glycol, 1,2-ethanediol, malonic acid, glutaric acid, 3-hydroxy butyric acid, propionic acid, phthalic acid, iso-phthalic acid, 3-hydroxy salicylic acid, 3,5-dihydroxy salicylic acid, gallic acid, benzoic acid and maleic acid, and salts thereof as well as amino-polycarboxylic acids and salts thereof.

As the amino-polycarboxylic acids and salts thereof, usable herein include, for instance, ethylenediamine-N,N,N′,N′-tetraacetic acid, diethylene triamine pentaacetic acid, 1,3-diaminiopropane-N,N,N′,N′-tetraacetic acid, ethylenediamine-N,N′-disuccinic acid (racemate), ethylenediamine disuccinic acid (SS isomer), N-(2-carboxylate ethyl)-L-aspartic acid, N-(carboxymethyl)-L-aspartic acid, β-alanine diacetic acid, methylimino-diacetic acid, nitrilotriacetic acid, cyclohexanediamine tetraacetic acid, imino-diacetic acid, glycol ether diamine tetraacetic acid, ethylenediamine-N,N′-diacetic acid, ethylenediamine-o-hydroxy-phenyl acetic acid, N,N-bis(2-hydroxybenzyl)ethylenediamine-N,N-diacetic acid and salts thereof. Examples of such salts are preferably alkali metal salts and ammonium salts and, in particular, ammonium salts.

Among these, preferably used herein as the foregoing oxidizing agents include hydrogen peroxide, nitric acid, potassium periodate, hypochlorous acid and ozone-containing water.

The amount of such oxidizing agents to be incorporated into the polishing liquid preferably ranges from 0.003 to 8 moles, more preferably 0.03 to 6 moles and particularly preferably 0.1 to 4 moles, per liter of the metal-polishing liquid practically used in polishing. More specifically, the added amount of the oxidizing agent is preferably not less than 0.003 moles since this would permit achievement of a high ability to oxidize metals and in turn ensure a high CMP speed, while the added amount thereof is not more than 8 moles, in order to prevent the formation of any rough surface after the polishing operation.

### [Organic Acid]

The metal-polishing liquid of the present invention preferably comprises an organic acid simultaneous with the foregoing ingredients. The “organic acid” herein used means a compound whose structure is different from that of the oxidizing agent used for the oxidation of the metal to be processed and accordingly, the organic acid never includes acids capable of serving as oxidizing agents described above.

The organic acids desirably used herein include those selected from the compounds listed below: formic acid, acetic acid, propionic acid, butyric acid, valeric acid, 2-methyl butyric acid, n-hexanoic acid, 3,3-dimethyl butyric acid, 2-ethyl butyric acid, 4-methyl pentanoic acid, n-heptanoic acid, 2-methyl hexanoic acid, n-octanoic acid, 2-ethyl hexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, and amino acids (the amino acids herein include primary, secondary and tertiary amino acids and amino-polycarboxylic acids and, in the present invention, preferably used include water-soluble amino acids such as glycine, L-alanine, β-alanine, L-2-amino butyric acid, L-norvaline, L-valine, L-leucine, L-norleucine, L-isoleucine, L-alloisoleucine, L-phenylalanine, L-proline, sarcosine, L-ornithine, L-lysine, taurine, L-serine, L-threonine, L-allothreonine, L-homoserine, L-tyrosine, 3,5-diiodo-L-tyrosine, β-(3,4-dihydroxyphenyl)-L-alanine, L-thyroxine, 4-hydroxy-L-proline, L-cysteine, L-methionine, L-ethionine, L-lanthionine, L-cystathionine, L-cystine, L-cysteic acid, L-aspartic acid, L-glutamic acid, S-(carboxymethyl)-L-cysteine, 4-aminobutyric acid, L-asparagine, L-glutamine, azaserine, L-arginine, L-canavanine, L-citrulline, δ-hydroxy-L-lysine, creatine, L-kynurenine, L-histidine, 1-methyl-L-histidine, 3-methyl-L-histidine, ergothioneine, L-tryptophan, Actinomycin C1, Apamin, Angiotensin I, Angiotensin II and Antipain), compounds represented by the following general formulas (1) and (2) and ammonium salts and alkali metal salts thereof.

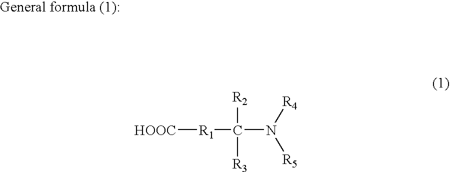

wherein, R₁ represents a single bond, an alkylene group or a phenylene group. R₂ and R₃ each independently represent a hydrogen atom, a halogen atom, a carboxyl group, an alkyl group, a cycloalkyl group, an alkenyl group, an alkynyl group or an aryl group. R₄ and R₅ each independently represent a hydrogen atom, a halogen atom, a carboxyl group, an alkyl group or an acyl group, provided that if R₁ represents a single bond, at least one of these groups R₄ and R₅ is not a hydrogen atom.

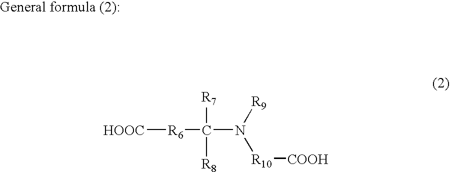

wherein, R₆ represents a single bond, an alkylene group or a phenylene group, R₇ and R₈ each independently represent a hydrogen atom, a halogen atom, a carboxyl group, an alkyl group, a cycloalkyl group, an alkenyl group, an alkynyl group or an aryl group, R₉ represents a hydrogen atom, a halogen atom, a carboxyl group, or an alkyl group, R₁₀ represents an alkylene group, provided that if R₁₀ represents a group: —CH₂—, at least one of the following requirements should be satisfied: R₆ is not a single bond; and R₉ is not a hydrogen atom.

The alkylene group represented by R₁ of Formula (1) may be a linear, branched or cyclic one and preferably used herein include alkylene groups each having 1 to 8 carbon atoms such as methylene and ethylene groups. These alkylene groups may have substituents and specific examples thereof are hydroxyl group and halogen atoms.

The alkyl groups represented by the groups R₂ and R₃ are preferably those each having 1 to 8 carbon atoms such as methyl and propyl groups. The cycloalkyl groups represented by the groups R₂ and R₃ are preferably those each having 5 to 15 carbon atoms such as cyclopentyl, cyclohexyl and cyclooctyl groups. The alkenyl groups represented by the groups R₂ and R₃ are preferably those each having 2 to 9 carbon atoms such as vinyl, propenyl, allyl groups. The alkynyl groups represented by the groups R₂ and R₃ are preferably those each having 2 to 9 carbon atoms such as ethynyl, propynyl and butynyl groups.

The aryl groups represented by the groups R₂ and R₃ are preferably those each having 6 to 15 carbon atoms such as phenyl group. These groups may include a hetero atom selected from, for instance, oxygen and sulfur atoms within the alkylene chains thereof. Each group represented by R₂ or R₃ may have a substituent selected from the group consisting of, for instance, a hydroxyl group, halogen atoms, aromatic rings (preferably those having 3 to 15 carbon atoms), a carboxyl group and amino groups.

The alkyl groups represented by the groups R₄ and R₅ are preferably those each having 1 to 8 carbon atoms such as methyl and ethyl groups. The acyl groups are preferably those each having 2 to 9 carbon atoms such as a methyl-carbonyl group. Each group represented by R₄ or R₅ may have a substituent selected from the group consisting of hydroxyl and amino groups and halogen atoms.

In the general formula (1), it is preferred that either one of R₄ and R₅ is not a hydrogen atom.

In addition, it is particularly preferred that, in the general formula (1), R₁ represents a single bond and R₂ and R₄ represent hydrogen atoms. In this case, R₃ represents a hydrogen atom, a halogen atom, a carboxyl group, an alkyl group, a cycloalkyl group, an alkenyl group, an alkynyl group or an aryl group and this preferably represents a hydrogen atom or an alkyl group, among others. R₅ represents a hydrogen atom, a halogen atom, a carboxyl group, an alkyl group or an acyl group, but it preferably represents an alkyl group among others. The alkyl group represented by R₃ may have a substituent, which is preferably selected from the group consisting of hydroxyl, carboxyl and amino groups. The alkyl group represented by R₅ may likewise have a substituent, which is preferably selected from the group consisting of hydroxyl and amino groups.

The alkylene groups represented by the substituents R₆ and R₁₀ of the compounds of Formula (2) may be linear, branched or cyclic ones and they are preferably those each having 1 to 8 carbon atoms such as methylene and ethylene groups. The alkylene and phenylene groups may further have substituents and examples thereof include a hydroxyl group and halogen atoms.

The alkyl groups represented by the substituents R₇ and R₈ are preferably those each having 1 to 8 carbon atoms such as methyl and propyl groups. The cycloalkyl groups represented by the substituents R₇ and R₈ are preferably those each having 5 to 15 carbon atoms such as cyclopentyl, cyclohexyl and cyclooctyl groups. The alkenyl groups represented by the substituents R₇ and R₈ are preferably those each having 2 to 9 carbon atoms and specific examples thereof include vinyl, propenyl and allyl groups. The alkynyl groups represented by the substituents R₇ and R₈ are preferably those each having 2 to 9 carbon atoms and specific examples thereof include ethynyl, propynyl and butynyl groups.

The aryl groups represented by the substituents R₇ and R₈ are preferably those each having 6 to 15 carbon atoms and specific examples thereof include phenyl groups. These groups may include a hetero atom selected from, for instance, oxygen and sulfur atoms within the alkylene chains thereof. Each group represented by R₇ or R₈ may have a substituent selected from the group consisting of, for instance, a hydroxyl group, halogen atoms and aromatic rings (preferably those having 3 to 15 carbon atoms).

The alkyl groups represented by the substituent R₉ are preferably those each having 1 to 8 carbon atoms such as methyl and ethyl groups. The acyl groups represented by the substituent R₉ are preferably those each having 2 to 9 carbon atoms such as a methyl-carbonyl group. These groups may include a hetero atom selected from, for instance, oxygen and sulfur atoms within the alkylene chains thereof. Each group represented by R₉ may have a substituent selected from the group consisting of hydroxyl, amino and carboxyl groups and halogen atoms.

In Formula (2), it is preferred that the substituent R₉ does not represent a hydrogen atom.

Specific examples of the compounds represented by the general formula (1) or (2) will be listed below, but the present invention is not restricted to these specific examples at all:

TABLE 1
(1)

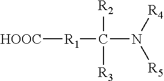

| | R₁ | R₂ | R₃ | R₄ | R₅ |
|---|---|---|---|---|---|
| A-1 | — | —H | —H | —H | —CH₃ |
| A-2 | — | —H | —H | —H | —CH₂OH |
| A-3 | — | —H | —H | —CH₂OH | —CH₂OH |
| A-4 | — | —H | —H | —H | —CH₂CH₂OH |
| A-5 | — | —H | —H | —CH₂CH₂OH | —CH₂CH₂OH |
| A-6 | — | —H | —CH₃ | —H | —CH₂OH |
| A-7 | — | —H | —CH₃ | —CH₂CH₂OH | —CH₂CH₂OH |
| A-8 | — | —H | —CH₂OH | —H | —CH₂OH |
| A-9 | — | —H | —CH(CH₃)₂ | —CH₂OH | —CH₂OH |
| A-10 | — | —H | —Ph | —H | —(CH₂CH₂O)₂—H |
| A-11 | — | —H | 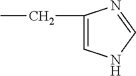 | —CH₂CH₂OH | —CH₂CH₂OH |
| A-12 | — | —H | —CH₂SCH₃ | —CH₂CH₂OH | —CH₂CH₂OH |
| A-13 | — | —H | —H | —H | —COCH₂NH₂ |
| A-14 | — | —H | —CH₂OH | —H | —COCH₂NH₂ |
| A-15 | — | —H | —H | —H | —COCH₃ |
| A-16 | —CH₂— | —H | —H | —CH₂CH₂OH | —CH₂CH₂OH |
| A-17 | —CH₂— | —H | —H | —H | —CH₂OH |
| A-18 | —CH₂— | —H | —H | —H | —COCH₂NH₂ |
| A-19 | —CH₂CH₂— | —H | —H | —H | —H |
| A-20 | — | —H | —CH₃ | —H | —CH₂CH₂OH |
| A-21 | — | —H | —CH₃ | —H | —CH₂OH |
| A-22 | — | —H | —CH₂CH₃ | —H | —CH₂CH₂OH |
| A-23 | — | —H | —CH₂CH₃ | —H | —CH₂OH |
| A-24 | — | —H | —CH₃ | —H | —CH₂CH₂NH₂ |
| A-25 | — | —H | —CH(CH₃)₂ | —H | —CH₂CH₂OH |
| A-26 | — | —H | —Ph | —H | —CH₂CH₂OH |
| A-27 | — | —H | —H | —H | —CH₂CH₂CH₂OH |

TABLE 2
(2)

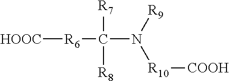

| | R₆ | R₇ | R₈ | R₉ | R₁₀ |
|---|---|---|---|---|---|
| B-1 | — | —H | —H | —CH₃ | —CH₂— |
| B-2 | — | —H | —H | —CH₂OH | —CH₂— |
| B-3 | — | —H | —H | —CH₂CH₂OH | —CH₂— |
| B-4 | — | —H | —H | —(CH₂CH₂O)₁₀—H | —CH₂— |
| B-5 | — | —H | —CH₃ | —CH₂CH₂OH | 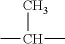 |
| B-6 | — | —H | —CH₃ | —H | 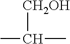 |
| B-7 | —CH₂— | —H | —CH₂OH | —CH₂CH₂OH | —CH₂— |
| B-8 | —CH₂— | —H | —H | —H | —CH₂CH₂— |
| B-9 | —CH₂— | —H | —H | —CH₂OH | —CH₂CH₂— |
| B-10 | —CH₂— | —H | —H | —H | —CH₂— |
| B-11 | — | —H | —CH₃ | —CH₂CH₂OH | —CH₂CH₂— |

The compounds represented by the general formula (1) or (2) can be prepared according to any known method, but it is also possible to use commercially available ones.

In particular, as the organic acids, the amino acid derivatives including the compounds represented by the general formulas (1) or (2) can preferably be used, since the use thereof would permit the effective control of the etching speed while maintaining a practically acceptable CMP speed.

The amount of the organic acid to be added preferably ranges from 0.0005 to 0.5 mole, more preferably 0.005 to 0.3 mole and particularly preferably 0.01 to 0.1 mole, per liter of the metal-polishing liquid practically used in polishing. More specifically, the added amount of the acid is preferably not more than 0.5 mole in view of the effective control of the etching rate, while it is not less than 0.0005 mole, for the purpose of achieving sufficiently high desired effects.

### [Inorganic Acid]

The metal-polishing liquid of the present invention may further comprise an inorganic acid. In this case, the acid may serve to accelerate the oxidation, to control the pH value of the polishing liquid, and/or as a buffering agent. Such inorganic acids may be, for instance, sulfuric acid, nitric acid, boric acid, and phosphoric acid and preferably used herein is phosphoric acid, among others.

The amount of the inorganic acid to be added preferably ranges from 0.0005 to 0.5 mole, more preferably 0.005 to 0.3 mole and particularly preferably 0.01 to 0.1 mole, per liter of the metal-polishing liquid practically used in polishing. More specifically, the added amount of the inorganic acid is preferably not more than 0.5 mole in view of the effective control of the etching rate, while it is not less than 0.0005 mole, for the purpose of ensuring sufficiently high desired effects.

### [Passive Film-Forming Agent (Aromatic Ring-Containing Compound)]

In addition, the metal-polishing liquid of the present invention may further include a compound having a function as a passive film-forming agent which can control any deterioration of the foregoing oxidizing agent, form a passive film on the metal surface to be processed and control the polishing rate, other than the aforementioned specific tetrazole derivative or specific 1,2,3-triazole derivative. More specifically, the metal-polishing liquid may comprise an aromatic ring-containing compound simultaneous with the foregoing specific tetrazole or triazole derivatives.

The “aromatic ring-containing compound” herein used means a compound including an aromatic ring such as a benzene ring or a naphthalene ring and having a molecular weight ranging from 20 to 600 and examples thereof include tetrazoles and derivatives thereof, anthranilic acids and derivatives thereof, amino-toluic acid, quinaldinic acid, and azoles such as those listed below:

Azoles as compounds each carrying an aromatic ring include, for instance, benzimidazole-2-thiol, 2-[2-(benzo-thiazolyl)]thio-propionic acid, 2-[2-(benzo-thiazolyl)]thio-butyric acid, 2-mercapto-benzothiazole, 1,2,3-triazole, 1,2,4-triazole, 3-amino-1H-1,2,4-triazole, benzotriazole, 1-hydroxy-benzotriazole, 1-dihydroxy-propyl-benzotriazole, 2,3-dicarboxypropyl-benzotriazole, 4-hydroxy-benzotriazole, 4-carboxy-1H-benzotriazole, 4-methoxycarbonyl-1H-benzotriazole, 4-butoxy-carbonyl-1H-benzotriazole, 4-octyloxycarbonyl-1H-benzotriazole, 5-hexylbenzo-triazole, N-(1,2,3-benzotriazolyl-1-methyl)-N-(1,2,4-triazolyl-1-methyl)-2-ethyl-hexylamine, tolyl-triazole, naphthyl-triazole and bis[(1-benzotriazolyl)methyl]phosphonic acid and preferably used herein include, for instance, benzotriazole, 4-hydroxy-benzotriazole, butyl ester of 4-carboxy-1H-benzotriazole, tolyl-triazole and naphtha-triazole, since these azoles would permit the achievement of not only a high CMP speed, but also a low etching rate or speed.

The total amount of the foregoing aromatic ring-containing compounds to be incorporated into the polishing liquid preferably ranges from 0.0001 to 1.0 mole, more preferably 0.001 to 0.5 mole and further preferably 0.01 to 0.1 mole per liter of the metal-polishing liquid practically used in polishing (more specifically, when diluted with water or an aqueous solution, this corresponds to the polishing liquid obtained after the dilution; those appearing in the following description are likewise shown in the same way).

In other words, the added amount of the aromatic ring-containing compound is preferably not more than 1.0 mole per liter of the metal-polishing liquid practically used in polishing, from the viewpoint of the prevention of any deterioration of the aforementioned oxidizing agent and these compounds (such as the invalidation and/or decomposition thereof), while it is preferably not less than 0.0001 mole in order to ensure the achievement of the desired effects of the present invention.

In this respect, the metal-polishing liquid of the present invention may likewise comprise thiocyanates, thio-ethers, thiosulfates or meso-ionic compounds in an amount smaller than that of the aromatic ring-containing compound simultaneous with the latter.

### [Chelating Agent]

It is preferred that the metal-polishing liquid of the present invention, if necessary, comprises a chelating agent (or a water softener) in order to reduce or relieve any adverse effect originated from, for instance, contaminated polyvalent metal ions.

Such a chelating agent may be widely and commonly used water softeners serving as suspension stabilizers for calcium and magnesium or compounds similar thereto and specific examples thereof include nitrilotriacetic acid, diethylene-triamine-pentaacetic acid, ethylenediamine-tetraacetic acid, N,N,N-trimethylene-phosphonic acid, ethylenediamine-N,N,N′,N′-tetramethylene-sulfonic acid, trans-cyclohexane-diamine-tetraacetic acid, 1,2-diamino-propane-tetraacetic acid, glycol ether diamine-tetraacetic acid, ethylenediamine-o-hydroxy-phenyl acetic acid, ethylenediamine disuccinic acid (SS isomer), N-(2-carboxylate ethyl)-L-aspartic acid, β-alanine diacetic acid, 2-phosphonobutane-1,2,4-tricarboxylic acid, 1-hydroxy-ethylidene-1,1-diphosphonic acid, N,N′-bis(2-hydroxybenzyl)ethylene-diamine-N,N′-diacetic acid, and 1,2-dihydroxybenzene-4,6-disulfonic acid.

These chelating agents may be used alone or, if necessary, in any combination of at least two of them. In this respect, the chelating agent should be used in an amount sufficient for sequestering, for instance, metal ions such as contaminated polyvalent metal ions and accordingly, the chelating agent is incorporated into the polishing liquid in an amount, for instance, ranging from 0.0003 to 0.07 mole per liter of the metal-polishing liquid practically used in polishing.

### [Additives]

Moreover, it is preferred that the metal-polishing liquid of the present invention comprises the following additives: ammonia; an alkylamine such as dimethylamine, trimethylamine, triethylamine, and propylene-diamine, or amines such as ethylenediamine-tetraacetic acid (EDTA), sodium diethyldithio-carbamic acid and chitosan; imines such as dithizone, cuproin (2,2′-biquinoline), neocuproin (2,9-dimethyl-1,10-phenanthroline), vasocuproin (2,9-dimethyl-4,7-diphenyl-1,10-phenanthroline), and cuperazone (bis-cyclohexanone-oxalyl-hydrazone); azoles such as benzimidzole-2-thiol, 2-[2-(benzothiazolyl)]-thiopropionic acid, 2-[2-(benzothiazol-yl)]-thiobutyric acid, 2-mercapto-benzothiazole, 1,2,3-triazole, 1,2,4-triazole, 3-amino-1H-1,2,4-triazole, benzotriazole, 1-hydroxy-benzotriazole, 1-dihydroxy-propyl-benzotriazole, 2,3-dicarboxypropyl-benzotriazole, 4-hydroxy-benzotriazole, 4-carboxy-1H-benzotriazole, 4-methoxycarbonyl-1H-benzotriazole, 4-butoxy-carbonyl-1H-benzotriazole, 4-octyloxycarbonyl-1H-benzotriazole, 5-hexyl-benzotriazole, N-(1,2,3-benzotriazolyl-1-methyl)-N-(1,2,4-triazolyl-1-methyl)-2-ethyl-hexyl-amine, tolyl-triazole, naphtho-triazole and bis[(1-benzotriazolyl)-methyl]phosphonic acid; mercaptans such as nonyl-mercaptan, dodecyl-mercaptan, triazine-thiol, triazine-dithiol, and triazine-trithiol; and further anthranilic acid, amino-toluic acid and quinaldinic acid. Among these additives, preferably used herein include chitosan, ethylenediamine-tetraacetic acid, L-tryptophan, cuperazone, triazine-dithiol, benzotriazole, 4-hydroxy-benzotriazole, butyl ester of 4-carboxy-1H-benzotriazole, tolyl-triazole and naphtho-triazole, in view of the simultaneous achievement of a high CMP speed and a low etching rate.

These additives are incorporated into the polishing liquid preferably in an amount ranging from 0.0001 to 0.5 mole, more preferably 0.001 to 0.2 mole and particularly preferably 0.005 to 0.1 mole, per liter of the metal-polishing liquid practically used in polishing. More specifically, the added amount of these additives is preferably not less than 0.0001 mole, in view of the effective control of the etching rate, while it is preferably not more than 0.5 mole for the prevention of any reduction of the CMP speed.

[Surfactant and/or Hydrophilic Polymer]

Preferably, the metal-polishing liquid of the present invention further comprises a surfactant and/or a hydrophilic polymer. These surfactant and hydrophilic polymer have such functions that both of them can reduce the contact angle between the plane of a substrate to be polished and the polishing liquid and that they can thus ensure uniform polishing operations. Examples of such surfactants and/or hydrophilic polymers suitably used in the present invention include a member selected from the group consisting of those specified below:

As anionic surfactants, there can be listed, for instance, carboxylic acid salts, sulfonic acid salts, sulfuric acid ester salts and phosphoric acid ester salts, and specific examples thereof include soap, N-acyl amino acid salts, carboxylic acid salts of polyoxyethylene or polyoxypropylene alkyl ether, and acylated peptides as carboxylic acid salts; alkyl-sulfonic acid salts, alkyl-benzene and alkyl-naphthalene sulfonic acid salts, naphthalene-sulfonic acid salts, sulfo-succinic acid salts, α-olefin sulfonic acid salts, and N-acyl-sulfonic acid salts as sulfonic acid salts; sulfated oils, alkyl-sulfuric acid salts, alkyl ether sulfate salts, polyoxyethylene or polyoxypropylene alkyl ether sulfate salts and alkylamide sulfate salts as sulfuric acid ester salts; and alkyl-phosphoric acid salts, and polyoxyethylene or polyoxypropylene alkyl ether phosphate salts as phosphoric acid ester salts.

As cationic surfactants, there can be listed, for instance, aliphatic amine salts, aliphatic quaternary ammonium salts, benzalkonium chloride, benzethonium chloride, pyridinium salts and imidazolinium salts. As amphoteric surfactants, there may be listed, for instance, carboxy betaine type ones, amino-carboxylic acid salts, imidazolinium betaines, lecithin and alkylamine oxides.

As nonionic surfactants, usable herein include, for instance, ether type ones, ether-ester type ones, ester type ones, and nitrogen atom-containing type ones and specific examples thereof are polyoxyethylene alkyl and alkyl phenyl ethers, alkyl-allyl formaldehyde-condensed polyoxyethylene ethers, polyoxyethylene/polyoxypropylene block copolymers and polyoxyethylene/polyoxypropylene alkyl ethers as ether type ones; polyoxyethylene ethers of glycerin esters, polyoxyethylene ethers of sorbitan esters and polyoxyethylene ethers of sorbitol esters, as ether-ester type ones; polyethylene glycol fatty acid esters, glycerin esters, polyglycerin esters, sorbitan esters, propylene glycol esters and sucrose esters, as ester type ones; and fatty acid alkanol-amides, polyoxyethylene fatty acid amides and polyoxyethylene alkylamides, as nitrogen atom-containing type ones.

Furthermore, as other surfactants, hydrophilic compounds, hydrophilic polymers or the like, there can be listed, for instance, esters such as glycerin esters, sorbitan esters, methoxy-acetic acid, ethoxy-acetic acid, 3-ethoxy-propionic acid and alanine ethyl ester; ethers such as polyethylene glycol, polypropylene glycol, polytetramethylene glycol, polyethylene glycol alkyl ethers, polyethylene glycol alkenyl ethers, alkyl polyethylene glycols, alkyl polyethylene glycol alkyl ethers, alkyl polyethylene glycol alkenyl ethers, alkenyl polyethylene glycols, alkenyl polyethylene glycol alkyl ethers, alkenyl polyethylene glycol alkenyl ethers, polypropylene glycol alkyl ethers, polypropylene glycol alkenyl ethers, alkyl polypropylene glycols, alkyl polypropylene glycol alkyl ethers, alkyl polypropylene glycol alkenyl ethers, alkenyl polypropylene glycols, alkenyl polypropylene glycol alkyl ethers and alkenyl polypropylene glycol alkenyl ethers; polysaccharides such as alginic acid, pectic acid, carboxymethyl cellulose, curdlan and pullulan; amino acid salts such as ammonium salt of glycine and sodium salt of glycine; polycarboxylic acids and salts thereof such as poly(aspartic acid), poly(glutamic acid), poly(lysine), poly(malic acid), poly(methacrylic acid), ammonium salt of poly(methacrylic acid), sodium salt of poly(methacrylic acid), poly(amide acids), poly(maleic acid), poly(itaconic acid), poly(fumaric acid), poly(p-styrene carboxylic acid), poly(acrylic acid), poly(acrylamide), amino poly(acrylamide), ammonium salt of poly(acrylic acid), sodium salt of poly(acrylic acid), poly(amido-acid), ammonium salt of poly(amido-acid), sodium salt of poly(amido-acid) and poly(glyoxylic acid); vinylic polymers such as polyvinyl alcohol, polyvinyl pyrrolidone and poly(acrolein); sulfonic acids and salts thereof such as ammonium salt of methyl taurine acid, sodium salt of methyl taurine acid, sodium salt of methyl sulfate, ammonium salt of ethyl sulfate, ammonium salt of butyl sulfate, sodium salt of vinyl sulfonate, sodium salt of 1-allyl sulfonate, sodium salt of 2-allyl sulfonate, sodium salt of methoxy-methyl sulfonate, ammonium salt of ethoxy-methyl sulfonate, sodium salt of 3-ethoxy-propyl sulfonate, sodium salt of methoxy-methyl sulfonate, ammonium salt of ethoxy-methyl sulfonate, sodium salt of 3-ethoxy-propyl sulfonate and sodium sulfo-succinate; and amides such as propionamide, acrylamide, methyl urea, nicotinamide, succinic acid amide and sulfanilamide.

In case where the polishing liquid of the present invention is applied to a substrate such as a silicon substrate for manufacturing semiconductor integrated circuits, however, it is quite undesirable that such a substrate is contaminated with alkali metals, alkaline earth metals, and halogen atoms and accordingly, the foregoing additives usable herein are desirably acids and ammonium salts thereof. Contrary to this, there is not any such limitation when a glass substrate or the like is used as such a substrate to be processed. More preferably used herein include cyclohexanol, ammonium salt of poly(acrylic acid), polyvinyl alcohol, succinic acid amide, polyvinyl pyrrolidone, polyethylene glycol, polyoxyethylene polyoxy-propylene block copolymer, among the compounds exemplified above.

The amount of these surfactants and/or hydrophilic polymers to be incorporated into the polishing liquid preferably ranges from 0.001 to 10 g, more preferably 0.01 to 5 g and particularly preferably 0.1 to 3 g per liter of the metal-polishing liquid practically used in polishing. In other words, the amount of the surfactant and/or hydrophilic polymer to be added is preferably not less than 0.001 g to ensure the achievement of the sufficient intended effects of the invention, while it is likewise preferably not more than 10 g, to prevent any reduction of the CMP speed. These surfactants and/or hydrophilic polymers each have a weight average molecular weight ranging from 500 to 100,000 and particularly preferably 2,000 to 50,000.

### [Alkaline Agent and Buffering Agent]

The metal-polishing liquid of the present invention may, if necessary, comprise an alkaline agent for the adjustment of the pH value thereof and the liquid may further comprise a buffering agent for inhibiting the occurrence of any fluctuation in the pH value.

Such alkaline agents and buffering agents usable herein include, for instance, non-metallic alkaline agents, for instance, ammonium hydroxide, organic ammonium hydroxides such as tetramethyl-ammonium hydroxide, and alkanol-amines such as di-ethanolamine, tri-ethanolamine and tri-isopropanol-amine; alkali metal hydroxides such as sodium hydroxide, potassium hydroxide, and lithium hydroxide; carbonic acid salts, phosphoric acid salts, boric acid salts, tetraborates, hydroxy-benzoic acid salts, glycyl salts, N,N-dimethyl glycine salts, leucine salts, norleucine salts, guanine salts, 3,4-dihydroxy-phenylalanine salts, alanine salts, amino-butyric acid salts, 2-amino-2-methyl-1,3-propanediol salts, valine salts, proline salts, tris(hydroxy)amino-methane salts and lysine salts.

Specific examples of such alkaline agents and buffering agents usable herein include sodium hydroxide, potassium hydroxide, lithium hydroxide, sodium carbonate, potassium carbonate, sodium bicarbonate, potassium bicarbonate, tri-sodium phosphate, tri-potassium phosphate, di-sodium phosphate, di-potassium phosphate, sodium borate, potassium borate, sodium tetraborate (borax), potassium tetraborate, sodium o-hydroxy-benzoate (sodium salicylate), potassium o-hydroxy-benzoate, sodium 5-sulfo-2-hydroxy-benzoate (sodium 5-sulfosalicylate), potassium 5-sulfo-2-hydroxy-benzoate (potassium 5-sulfosalicylate), and ammonium hydroxide.

Particularly preferably used alkaline agents are ammonium hydroxide, potassium hydroxide, lithium hydroxide and tetramethyl-ammonium hydroxide.

The added amount of these alkaline agents and buffering agents is not restricted to any specific range insofar as the pH value of the resulting polishing liquid can be maintained at a level falling within a desired range and specifically, the amount thereof preferably ranges from 0.0001 to 1.0 mole, and more preferably 0.003 to 0.5 mole per liter of the metal-polishing liquid practically used in polishing.

The pH value of the metal-polishing liquid practically used in polishing preferably falls within the range of from 2 to 14, more preferably 3 to 12 and most preferably 3.5 to 8. The metal-polishing liquid of the present invention shows particularly excellent effects when the pH value thereof falls within the range specified above.

In the present invention, the kinds and amounts of compounds to be used and the pH value of the finally prepared polishing liquid should appropriately be selected or established while taking into consideration the following various factors: the adsorptivity of the resulting polishing liquid to the plane to be polished and the reactivity of the former with the latter, the solubility of the metal to be polished in the polishing liquid, the electrochemical characteristics of the plane to be polished the dissociated conditions of the functional groups of the compounds selected and the stability of the polishing liquid in its liquid state.

### [Abrasive Grains]

The metal-polishing liquid of the present invention may comprise abrasive grains. Examples of such abrasive grains preferably used herein are silica particles (precipitated silica, fumed silica, colloidal silica and synthetic silica particles), ceria, alumina, titania, zirconia, germania, manganese oxide, silicon carbide, polystyrene, polyacrylic resin, and polyterephthalate.

The abrasive grains preferably have an average particle size ranging from 5 to 1000 nm and, in particular, 10 to 200 nm.

The amount of the abrasive grains to be incorporated into the polishing liquid preferably ranges from 0.01 to 20% by mass and more preferably 0.05 to 5% by mass on the basis of the total mass of the metal-polishing liquid practically used in polishing. This is because the added amount thereof is preferably not less than 0.01% by mass in order to obtain sufficient desired effects such as the improvement of the polishing speed and the reduction of the fluctuation in the polishing speed on the whole polished plane of a wafer, while the upper limit thereof is likewise preferably not more than 20% by mass, since the polishing speed in the CMP step is almost saturated when the added amount thereof exceeds the upper limit.

### [Raw Metallic Material for Forming Wirings]

In the present invention, a semiconductor device as a subject to be polished is preferably an LSI device provided with wirings made of metal copper and/or a copper alloy and in particular, an LSI device provided with wirings made of a copper alloy. In the present invention, the following expression: “the metal-polishing liquid is used for principally polishing copper wirings” means that the metal-polishing liquid is used for polishing a semiconductor wafer as a subject to be polished, which is provided thereon with a plated or deposited layer of metal copper and/or a copper alloy. Moreover, preferred copper alloys are those containing silver, among others. The content of silver included in the copper alloy is preferably not more than 40% by mass, in particular, not more than 10% by mass and more preferably not more than 1% by mass. Accordingly, the most excellent effect can be expected when using a copper alloy having a silver content ranging from 0.00001 to 0.1% by mass.

### [Line Thickness of Wiring]

In the present invention, the semiconductor devices as the subjects to be polished are preferably LSI devices, for instance, DRAM devices each provided with wirings having a line size, as expressed in terms of the half pitch, of not more than 0.15 μm, in particular, not more than 0.10 μm and more preferably not more than 0.08 μm; and MPU devices each provided with wiring having a line size, as expressed in terms of the half pitch, of not more than 0.12 μm, in particular, not more than 0.09 μm and more preferably not more than 0.07 μm. The metal-polishing liquid of the present invention would show particularly excellent effects when applying the same to these LSI devices.

### [Barrier Metals]

In the present invention, it is preferred that the semiconductor device as the subject to be polished with the metal-polishing liquid of the invention is provided with a barrier layer between wirings made of metal copper and/or a copper alloy and an interlayer insulator film, for the purpose of preventing the occurrence of any diffusion of copper. The material for forming such a barrier layer is preferably a metallic material having a low electric resistance and preferably used herein include, in particular, TiN, TiW, Ta, TaN, W and WN, with Ta and TaN being particularly preferably used herein among others.

### [Polishing Process]

The metal-polishing liquid may initially be prepared in the form of a concentrated liquid and it may then be diluted with water to give a metal-polishing liquid practically used in polishing immediately before the practical use; or the components each in the form of an aqueous solution as will be detailed in the following section may be mixed together and the resulting mixture may, if necessary, be diluted with water to give a metal-polishing liquid practically used in polishing; or the metal-polishing liquid may be prepared, at the beginning, in the form of a metal-polishing liquid practically used in polishing. The metal-polishing method according to the present invention makes use of the metal-polishing liquid of the present invention and this method can be applied to either of the foregoing cases. In other words, the method comprises the steps of supplying the metal-polishing liquid to a polishing pad on a polishing board to thus bringing the polishing liquid into contact with the surface or the plane of a subject to be polished and making the plane and the polishing pad to undergo relative motions to thus polish the surface of the subject.

As polishing apparatuses usable herein may be, for instance, a commonly used one comprising a holder for supporting a subject having a plane to be polished such as a semiconductor substrate and a polishing board to which a polishing pad is adhered and which is equipped with, for instance, a motor whose number of revolutions can arbitrarily be controlled. The polishing pad usable herein is not restricted to any particular one and it may be, for instance, those made of widely used nonwoven fabrics, foamed polyurethane, or porous fluorine plastics. Moreover, there is not any restriction in the conditions for polishing, but the rotational frequency of the polishing board is preferably set at a level of not more than 200 rpm so that the substrate never springs out of the polishing board. The pressure required for pushing a semiconductor substrate having a plane to be polished (a film to be polished) against the polishing pad is preferably set at a level on the order of 5 to 500 g/cm², and more preferably 12 to 240 g/cm² in order to ensure the uniformity of the polishing speed within the whole surface of the wafer and the flatness of the pattern of wiring formed on the wafer surface.

The metal-polishing liquid is continuously supplied onto the polishing pad by the action of, for instance, a pump throughout the polishing operation. The amount of the polishing liquid to be supplied thereto is not restricted to any specific range, but it is preferably supplied in such a manner that the surface of the polishing pad is always covered with the polishing liquid. After the completion of the polishing operation, the polished semiconductor substrate is sufficiently washed with running water. Subsequently, any water drop adhered to the semiconductor substrate is removed through the use of, for instance, a spin dryer and then dried. In the polishing method of the present invention, an aqueous solution used for the dilution of the metal-polishing liquid is identical to an aqueous solution as will be described below. Such an aqueous solution comprises water which contains at least one member selected from the group consisting of an oxidizing agent, an acid, additives and a surfactant, incorporated therein in advance in such a manner that the sum of each component present in the aqueous solution and in the metal-polishing liquid to be diluted with the former is adjusted to the level practically required for the final metal-polishing liquid used in the subsequent polishing operation. When using the metal-polishing liquid after the dilution with such an aqueous solution, any hardly soluble component can be incorporated into the polishing liquid in the form of an aqueous solution and accordingly, it is possible to prepare a more concentrated metal-polishing liquid as a stock solution.

As a method for diluting such a concentrated metal-polishing liquid by the addition of water or an aqueous solution, usable herein is one which comprises the step of mixing the concentrated metal-polishing liquid with water or such an aqueous solution by connecting a pipe for supplying the former to the polishing pad with that for supplying the latter in the middle of the former pipe to thus supply the resulting mixed and diluted polishing liquid to the polishing pad. These liquids may be mixed together according to any method conventionally used such as a method which comprises injecting these liquids through corresponding narrow passages while applying a pressure to thus admix them; a method which comprises packing fillers such as fine glass tubes into a pipe and then passing these liquid through the pipe to repeatedly separate or branch and combine these liquids to thus obtain a uniform mixture; or a method in which a blade capable of being operated by the action of any power is arranged within the piping for supplying these liquid to the pad.

The feed rate of the metal-polishing liquid preferably ranges from 10 to 1000 ml/min and more preferably 170 to 800 ml/min in order to ensure the uniformity of the polishing speed within the whole surface of the wafer and the desired flatness of the pattern of wirings formed on the wafer surface.

The polishing method in which a concentrated metal-polishing liquid is diluted with water or an aqueous solution more specifically comprises the steps of separately providing a pipe for supplying the metal-polishing liquid and a pipe for supplying water or such an aqueous solution, feeding, to a polishing pad, predetermined amounts of these liquids through the foregoing pipes and then making the plane of a subject for polishing and the polishing pad to undergo relative motions so that the surface of the subject is thus polished, while these liquids are mixed together. Alternatively, in another polishing method, desired amounts of a concentrated metal-polishing liquid and water or such an aqueous solution are introduced into a single container and then the resulting metal-polishing liquid thus prepared through mixing is supplied to a polishing pad to thus polish the surface of an intended subject.

In a further polishing method according to the present invention, the components required for preparing a metal-polishing liquid practically used in polishing are divided into at least two groups, followed by the dilution of these ingredients with water or an aqueous solution, the supply of the resulting diluted solutions to a polishing pad placed on a polishing board, and then bringing the surface of a subject to be polished into contact with these solutions in order to make the plane and the polishing pad to undergo relative motions between them to thus polish the surface of the subject.

For instance, an oxidizing agent is specified as one ingredient (A) for the metal-polishing liquid, while an acid, additives, a surfactant and water are specified as an ingredient (B) and these ingredients (A) and (B) are diluted with water or an aqueous solution, immediately before putting the metal-polishing liquid into practical use.

According to another embodiment, the additives having a low solubility are added in a separate group ((A) or (B)). That is, a group comprising an oxidizing agent, an additive and a surfactant is defined to be an ingredient (A), while another group containing an acid, an additive, a surfactant and water is defined to be another ingredient (B) and these ingredients (A) and (B) are diluted with water or an aqueous solution, immediately before putting the resulting metal-polishing liquid into practical use. In this case, the polishing apparatus requires the use of three pipes for supplying these ingredients (A) and (B) and for supplying water or an aqueous solution and accordingly, the dilution and mixing of these ingredients may be practiced by, for instance, a method in which these three pipes are combined into one pipe for supplying the resulting polishing liquid to a polishing pad and these three ingredients are admixed together within the latter pipe. Alternatively, to combine these three pipes, two of them may first be combined into one and then the combined pipe may further be combined with the remaining third pipe.

In this respect, the aforementioned specific heterocyclic derivative used as an essential component in the metal-polishing liquid of the present invention is preferably incorporated into the ingredient (B) out of the foregoing two ingredients, together with an organic acid, in order to ensure an improved stability of the resulting polishing liquid with the elapse of time.

For instance, one such method comprises the steps of first mixing an ingredient containing hardly soluble additives with one of the remaining ingredients, passing the resulting mixture through an extremely elongated passage to thus ensure a sufficient solubilization time and then combining this combined pipe with the final pipe for supplying, for instance, water or an aqueous solution. As further methods for mixing these ingredients, there can be listed, for instance, one in which all of these three pipes are directly guided to the polishing pad and these ingredients are admixed together by the action of the relative motions of a desired polishing pad and the plane of a subject to be polished; and one in which the three ingredients are mixed together in a single container and the resulting diluted metal-polishing liquid thus prepared is supplied to a desired polishing pas through the container, as has already been described above. In the polishing methods described above, it is also possible to maintain one of the ingredients containing the oxidizing agent at a temperature of not higher than 40° C., while warming another ingredient at a temperature ranging from room temperature to 100° C., and to combine one of the ingredients with another ingredient or to dilute the same with water or an aqueous solution prior to the practical use of the resulting polishing liquid in such a manner that the temperature of the resulting polishing liquid thus prepared may be controlled at a level of not more than 40° C. This is because if the temperature is high, the solubility of these ingredients correspondingly increases and for this reason, this method is quite suitable when it is necessary to increase the solubility of raw materials used in the metal-polishing liquid having insufficient solubility.

The ingredient obtained by dissolving the components of the metal-polishing liquid except for the oxidizing agent by raising the temperature from room temperature to 100° C. may undergo the formation of precipitations of these components in the metal-polishing liquid, when the ingredient thus prepared is cooled. If using such an ingredient containing precipitations at a low temperature, it must be warmed in advance to eliminate the precipitates through dissolution thereof. To this end, the following means can be used: a means for supplying the solution of the ingredient, which has been converted into a liquid by the dissolution of precipitate through warming; or a means for stirring a liquid containing precipitates and for feeding the liquid through a pipe while heating the pipe for the dissolution of the precipitates. In this connection, however, if one of the ingredients, which is free of any oxidizing agent and which is to be warmed increases the temperature of the metal-polishing liquid formed after the mixing operation up to a level of not less than 40° C., the oxidizing agent present in the resulting mixture may undergo decomposition. Accordingly, the warmed ingredient free of any oxidizing agent should be mixed with the ingredient which contains an oxidizing agent and which can cool the warmed ingredient in such a manner that the resulting mixture has a temperature of not more than 40° C.

In addition, the components required for preparing the metal-polishing liquid of the present invention may be divided into at least two groups as has been discussed above. In this case, it is preferred to divide them into a group or ingredient containing an oxidizing agent and a group or ingredient containing an acid prior to the supply of these components to a polishing pad. Alternatively, a liquid concentrate is used as a metal-polishing liquid practically used in polishing and diluting water is separately supplied onto the plane of a subject to be polished.

### [Pad]

The polishing pad used in the present invention may be either a pad having a foam-free structure or one having foamed structure. The former is one comprising a hard bulk material made of a synthetic resin such as a plastic plate as a pad, while the latter may be divided into three type ones or a pad having closed-cell foam (a foamed system prepared by the dry method), a pad having open-cell foam (a foamed system prepared by the wet method), and a two-layer composite type pad (a laminated type one), with the two-layer composite type pad (the laminated type one) being particularly preferred in the present invention. The foam included these pads may be either uniform or non-uniform one.

Furthermore, it is also possible to use, in the metal-polishing, a polishing pad containing abrasive grains (such as ceria, silica, alumina, and resins). In addition, it is likewise possible to use either a soft pad or a hard pad and it is preferred, in case of a laminated type one, to use layers having various values of hardness different from one another. Examples of materials for producing such a polishing pad preferably used herein include nonwoven fabrics, artificial leather cloths, polyamide, polyurethane, polyester, and polycarbonate. In addition, the face of such a pad, which comes in close contact with the plane or surface to be polished, may be subjected to desired processing treatments for forming lattice-like grooves/holes/concentric grooves/helical grooves.

### [Wafer]

The wafer as the subject to which the CMP technique is applied while using the metal-polishing liquid of the present invention has a diameter of not less than 200 mm and in particular, not less that 300 mm. Conspicuous effects of the present invention can be expected when using a wafer having a diameter of not less than 300 mm.

The following are preferred embodiments of the present invention:

(1) A metal-polishing liquid characterized in that it simultaneously comprises the compound of the present invention and at least one compound selected from the group consisting of those represented by the foregoing general formulas (1) and (2) as organic acids.
(2) A metal-polishing liquid characterized in that it simultaneously comprises the compound of the present invention and at least one compound selected from the group consisting of those represented by the foregoing general formulas (1) and (2) as organic acids and that the compound of the present invention is added to the metal-polishing liquid in a concentration of not more than one mole/L.
(3) A metal-polishing liquid characterized in that it simultaneously comprises the compound of the present invention and at least one compound selected from the group consisting of those represented by the foregoing general formulas (1) and (2) as organic acids and that the compound of the present invention is added to the metal-polishing liquid in a concentration of not more than 0.5 mole/L.
(4) A metal-polishing liquid for use in the polishing operation at a presser pressure of not more than 75 g/cm², characterized in that it simultaneously comprises the compound of the present invention and at least one compound selected from the group consisting of those represented by the foregoing general formulas (1) and (2) as organic acids and that the compound of the present invention is added to the metal-polishing liquid in a concentration of not more than 0.5 mole/L.

### EXAMPLE

The present invention will hereunder be described in more detail with reference to the following Examples, but the present invention is not restricted to these specific Examples at all.

### Example 1

A metal-polishing liquid (the metal-polishing liquid of Example 1) was prepared on the basis of the formulation (metal-polishing liquid 1). The resulting metal-polishing liquid was evaluated by subjecting the same to tests of polishing metals according to the following method.

### (Metal-Polishing Liquid 1)

| Component | Amount | |
|---|---|---|
| Hydrogen peroxide (oxidizing agent) | 5 | g/L |
| Glycine (organic acid) | 0.2 | mol/L |
| Compound I-1 (a specific tetrazole derivative) | 0.2 | mmol/L |
| Colloidal silica (abrasive grains) | 9 | g/L |
| Pure water | Ad. 1000 | mL |
| pH (adjusted using aqueous ammonia and | 6.7 | |
| sulfuric acid) | | |

### (Test of Polishing Metals)

Polishing Pad: IC1400XY-K Groove (available from Rodhel Company)

Polishing Apparatus: LGP-612 (available from LapmaSterSFT Company)

Presser Pressure: 75 g/cm²

Feed Rate of Polishing Liquid: 200 mL/min

Copper-Blanketed Wafer: A wafer on which a copper film is deposited in a thickness of 1.4 μm (diameter: 200 mm)

Tantalum-Blanketed Wafer: A wafer on which a tantalum film is deposited in a thickness of 1 μm (diameter: 200 mm)

Patterned Wafer: CMP854 Patterned Wafer (diameter: 200 mm) available from SEMATECH Company

Rotational Frequency of Polishing Pad/Wafer: 95/120 rpm

Temperature of Polishing Board: Controlled at 20° C.

### (Evaluation Method)

Polishing Rate: Copper- and tantalum-blanketed wafers were subjected to CMP processing, followed by determining the electric resistance of each metal film at arbitrarily selected 49 points on each surface of the wafer before and after the CMP treatment, converting the electric resistance values thus determined into film thicknesses to thus determine each average polishing rate.

Dishing: Each patterned wafer was polished over a time required for completely removing the copper existing on the wiring-free area through polishing and further polished for an additional time corresponding to 50% of the foregoing time, followed by the determination of any dishing on line and space areas (line: 100 μm; space: 100 μm) using a tracer type step meter.

The polishing rate, dishing and the ratio: Cu polishing rate/tantalum-polishing rate obtained after the foregoing CMP treatment carried out using the foregoing metal-polishing liquid are summarized in the following Table 3.

### Examples 2 to 5 and Comparative Examples 1 to 6

The same procedures used in Example 1 were repeated except that the compounds specified in the following Table 3 were substituted for Compound I-1 as a specific tetrazole derivative and the glycine as an organic acid, used in the formulation of the metal-polishing liquid 1 prepared in Example 1, to thus prepare metal-polishing liquids of Examples 2 to 5 and Comparative Examples 1 to 6 and the resulting metal-polishing liquids were likewise used in the evaluation tests identical to those used in Example 1. The results thus obtained are summarized in Table 3.

TABLE 3

| | Specific | | | | |
|---|---|---|---|---|---|
| | Heterocyclic | | | | Ratio of |
| | Derivative or | | Polishing | | Polishing |
| | Comparative | | rate of Cu | Dishing | Rate |
| Ex. No. | Hetero ring | Organic acid | (nm/min) | (nm) | (Cu/Ta) |
| 1 | Compound I-1 | Glycine | 480 | 110 | 350 |
| 2 | Compound I-1 | Imino- | 510 | 130 | 250 |
| | | diacetic acid | | | |
| 3 | Compound I-1 | Bicine** | 450 | 80 | 380 |
| 4 | Compound I-5 | Bicine** | 470 | 60 | 410 |
| 5 | Compound I-10 | Bicine** | 450 | 70 | 400 |
| 1* | Benzotriazole | Glycine | 310 | 100 | 120 |
| 2* | Benzotriazole | Imino- | 330 | 120 | 100 |
| | | diacetic acid | | | |
| 3* | Benzotriazole | Bicine** | 290 | 80 | 200 |
| 4* | 1H-Tetrazole | Glycine | 460 | 140 | 190 |
| 5* | 1H-Tetrazole | Imino- | 490 | 190 | 130 |
| | | diacetic acid | | | |
| 6* | 1H-Tetrazole | Bicine** | 440 | 110 | 250 |

*Comparative Example
**Bicine: N,N-bis(2-hydroxyethyl) glycine

The data listed in Table 3 clearly indicate that the metal-polishing liquid of the present invention containing a specific tetrazole derivative is excellent in the polishing rate and the dishing-inhibitory effect as compared with the comparative metal-polishing liquids containing benzotriazole and unsubstituted 1H-tetrazole, which are free of any specific functional group used in the present invention. Moreover, the foregoing test results likewise indicate that the metal-polishing liquid of the present invention has a high polishing selectivity ratio between copper and tantalum.

### Example 6

A metal-polishing liquid (the metal-polishing liquid of Example 6) was prepared on the basis of the formulation (metal-polishing liquid 2). The resulting metal-polishing liquid was evaluated by subjecting the same to tests of polishing metals according to the following method.

### (Metal-Polishing Liquid 2)

| Component | Amount | |
|---|---|---|
| Hydrogen peroxide (oxidizing agent) | 5 | g/L |
| Glycine (organic acid) | 15.0 | g/L |
| | (0.2 | mol/L) |
| Compound III-1 (specific 1,2,3-triazole derivative) | 0.2 | mmol/L |
| Colloidal silica (abrasive grains) | 9 | g/L |
| Pure water | Ad. 1000 | mL |
| pH (adjusted using aqueous ammonia and | 6.7 | |
| sulfuric acid) | | |

### (Test of Polishing Metals)

Polishing Pad: IC1400XY-K Groove (available from Rodhel Company)

Polishing Apparatus: LGP-612 (available from LapmaSterSFT Company)

Presser Pressure: 75 g/cm²

Feed Rate of Polishing Liquid: 200 mL/min

Copper-Blanketed Wafer: A wafer on which a copper film is deposited in a thickness of 1.4 μm (diameter: 200 mm)

Tantalum-Blanketed Wafer: A wafer on which a tantalum film is deposited in a thickness of 1 μm (diameter: 200 mm)

Patterned Wafer: CMP854 Patterned Wafer (diameter: 200 mm) available from SEMATECH Company

Rotational Frequency of Polishing Pad/Wafer: 95/120 rpm

Temperature of Polishing Board: Controlled at 20° C.

### (Evaluation Method)

Polishing Rate: Copper- and tantalum-blanketed wafers were subjected to CMP processing, followed by determining the electric resistance of each metal film at arbitrarily selected 49 points on each surface of the wafer before and after the CMP treatment, converting the electric resistance values thus determined into film thicknesses to thus determine each average polishing rate.

Dishing: Each patterned wafer was polished over a time required for completely removing the copper existing on the wiring-free area through polishing and further polished for an additional time corresponding to 50% of the foregoing time, followed by the determination of any dishing on line and space areas (line: 100 μm; space: 100 μn) using a tracer type step meter.

The polishing rate, dishing and the ratio: Cu polishing rate/tantalum-polishing rate obtained after the foregoing CMP treatment carried out using the foregoing metal-polishing liquid are summarized in the following Table 4.

### Examples 7 to 11 and Comparative Examples 7 to 9

The same procedures used in Example 6 were repeated except that the compounds specified in the following Table 3 were substituted for Compound III-1 as a specific 1,2,3-triazole derivative and the glycine as an organic acid, used in the formulation of the metal-polishing liquid 2 prepared in Example 6, to thus prepare metal-polishing liquids of Examples 7 to 11 and Comparative Examples 7 to 9 and the resulting metal-polishing liquids were likewise used in the evaluation tests identical to those used in Example 6. The results thus obtained are summarized in Table 4.

TABLE 4

| | Specific | | | | |
|---|---|---|---|---|---|
| | Heterocyclic | | | | Ratio of |
| | Derivative or | | Polishing | | Polishing |
| | Comparative | Organic | rate of Cu | Dishing | Rate |
| Ex. No. | Hetero-ring | acid | (nm/min) | (nm) | (Cu/Ta) |
| 6 | Compound III-1 | Glycine | 460 | 110 | 320 |
| 7 | Compound III-8 | Bicine** | 430 | 70 | 310 |
| 8 | Compound III-8 | Glycine | 460 | 110 | 300 |
| 9 | Compound III-8 | Bicine** | 420 | 80 | 330 |
| 10 | Compound III-18 | Glycine | 440 | 130 | 310 |
| 11 | Compound III-19 | Glycine | 440 | 130 | 300 |
| 7* | Benzotriazole | Glycine | 310 | 100 | 120 |
| 8* | Benzotriazole | Bicine** | 290 | 80 | 200 |
| 9* | 1,2,3-Triazole | Glycine | 450 | 180 | 230 |

*Comparative Example
**Bicine: N,N-bis(2-hydroxyethyl) glycine

The data listed in Table 4 clearly indicate that the metal-polishing liquid of the present invention which contains a specific 1,2,3-triazole derivative is excellent in the polishing rate and the dishing-inhibitory effect as compared with the comparative metal-polishing liquids containing heterocyclic derivatives other than those used in the present invention such as benzotriazole and unsubstituted 1,2,3-triazole, which are beyond the scope of the present invention. Moreover, the foregoing test results likewise indicate that all of the metal-polishing liquids of the present invention can ensure a high polishing selectivity ratio between copper and tantalum as compared with the comparative metal-polishing liquids.

What is claimed is:

1. A method of chemical mechanical polishing of a surface of a metal in a semiconductor device to flatten the surface, comprising steps of:
(i) providing a polishing liquid comprising (i-1) at least one compound selected from the group consisting of tetrazoles or triazoles represented by any one of the following general formulas (I) to (III) and (i-2) an organic acid that is at least one compound selected from the group consisting of amino acids and the compounds represented by the following general formulas (1) and (2) and ammonium salts or alkali metal salts thereof: 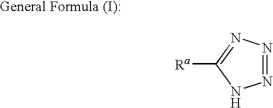
wherein, R^{a} represents at least one substituent selected from the group consisting of a sulfo group, an amino group, a phosphono group (—PO₃H₂), a carbamoyl group (—CONRR′), a carbamide group (—NHCOR″), a sulfamoyl group (—SO₂NH₂), and a sulfonamide group (—NHSO₂R″); R and R′ each independently represents a group selected from the group consisting of a hydrogen atom, alkyl groups and aryl groups; and R″ independently represents a group selected from the group consisting of alkyl groups and aryl groups. 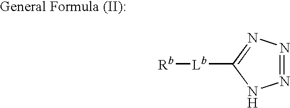
wherein, R^{b} represents at least one substituent selected from the group consisting of a hydroxyl group, a carboxyl group, a sulfo group, an amino group, a phosphono group (—PO₃H₂), a carbamoyl group (—CONRR′), a carbamide group (—NHCOR″), a sulfamoyl group (—SO₂NH₂), and a sulfonamide group (—NHSO₂R″); R and R′ each independently represents a group selected from the group consisting of a hydrogen atom, alkyl groups and aryl groups; R″ independently represents a group selected from the group consisting of alkyl groups and aryl groups; and L^{b} represents a divalent connecting group. 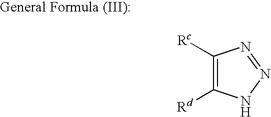
wherein, R^{c} and R^{d} each independently represents a hydrogen atom or a substituent, and at least one of R^{c} and R^{d} represent a hydroxyl group, a carboxyl group, a sulfo group, an amino group, a phosphono group (—PO₃H₂), a carbamoyl group (—CONRR′), a carbamide group (—NHCOR″), a sulfamoyl group (—SO₂NH₂), a sulfonamide group (—NHSO₂R″) or a group: -L^{a}-R^{e}; L^{a} represents a divalent connecting group; R^{e} represents a hydroxyl group, a carboxyl group, a sulfo group, an amino group, a phosphono group (—PO₃H₂), a carbamoyl group (—CONRR′), a carbamide group (—NHCOR″), a sulfamoyl group (—SO₂NH₂) or a sulfonamide group (—NHSO₂R″); R and R′ each independently represents a group selected from the group consisting of a hydrogen atom, alkyl groups and aryl groups; and R″ independently represents a group selected from the group consisting of alkyl groups and aryl groups; 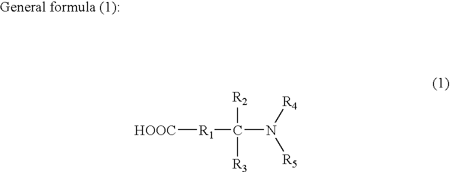
wherein, R₁ represents a single bond, an alkylene group or a phenylene group, R₂ and R₃ each independently represents a hydrogen atom, a halogen atom, a carboxyl group, an alkyl group, a cycloalkyl group, an alkenyl group, an alkynyl group or an aryl group, R₄ and R₅ each independently represents a hydrogen atom, a halogen atom, a carboxyl group, an alkyl group or an acyl group, provided that if R₁ represents a single bond, at least one of these groups R₄ and R₅ is not a hydrogen atom; 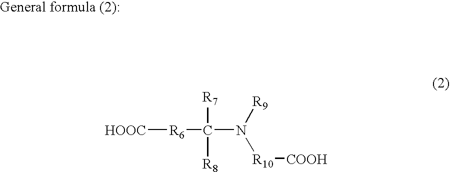
wherein, R₆ represents a single bond, an alkylene group or a phenylene group, R₇ and R₈ each independently represents a hydrogen atom, a halogen atom, a carboxyl group, an alkyl group, a cycloalkyl group, an alkenyl group, an alkynyl group or an aryl group, R₉ represents a hydrogen atom, a halogen atom, a carboxyl group, or an alkyl group, R₁₀ represents an alkylene group, provided that if R₁₀ represents a group: —CH₂—, at least one of the following requirements should be satisfied: R₆ is not a single bond; and R₉ is not a hydrogen atom,
(ii) bringing the polishing liquid into contact with a surface of the metal, and
(iii) making the surface of the metal and a polishing pad to undergo relative motions to thus polish the surface of the metal.

2. The method as set forth in claim 1, wherein the metal is wiring of metal copper and/or copper alloy.

3. The method as set forth in claim 1, comprising the compound selected from the group consisting of tetrazoles or triazoles represented by any one of the general formulas (I) to (III) in an amount ranging from 0.00001 to 1 mole/L.

4. The method as set forth in claim 1, the amount of the organic acid ranges from 0.0005 to 0.5 mole/L.

5. The method as set forth in claim 1, wherein the organic acid is at least one compound selected from the group consisting of amino acids and the compounds represented by general formula (1), wherein R¹ is a single bond, R² and R³ each represents a hydrogen atom, R⁴ and R⁵ each independently represents an alkyl group, which alkyl group independently represented by R⁴ and R⁵ may have a hydroxyl group as a substituent.

6. The method as set forth in claim 5, wherein the organic acid comprises bicine.

7. The method as set forth in claim 2, wherein the semiconductor device has a barrier layer comprising Ta or TaN.

8. The method as set forth in claim 7, which provides an improved selectivity to copper/tantalum in polishing operations.

9. The method as set forth in claim 1, wherein the polishing is conducted in the presence of abrasive grains.

10. The method as set forth in claim 1, wherein the pressure for pushing the surface of metal against the polishing pad is from 5 to 500 g/cm².
